(19) United States
(12) Patent Application Publication
(10) Pub. No.: US 2004/0157163 A1
(43) Pub. Date: Aug. 12, 2004

(54) Method of improving photoresist layer uniformity

(75) Inventors: Meng-Hung Chen, Taoyuan (TW); Hsin-Ling Wu, Taipei (TW); Hung-Mo Wu, Kaohsiung (TW); Chung-Yuan Lee, Taoyuan (TW)

Correspondence Address: QUINTERO LAW OFFICE, 1617 BROADWAY, 3RD FLOOR, SANTA MONICA, CA, 90404, US

(73) Assignee: Nanya Technology Corporation

(21) Appl. No.: 10/439,371

(22) Filed: May 16, 2003

(30) Foreign Application Priority Data
Feb. 11, 2003 (TW) 92102762

(51) Int. Cl. G03F 7/26

(52) U.S. Cl. 430/311; 430/314

(57) ABSTRACT

A method for improving photoresist layer uniformity and fabricating a lower electrode of a trench capacitor. First, a substrate having a plurality of trenches is provided. Next, a protective photoresist layer is formed on the substrate to fill the trenches. Parts of the protective photoresist layer are removed to form first openings in trenches. A refill photoresist layer with a planar upper surface is blanketly formed to fill the first openings. The protective photoresist and/or the refill photoresist layer are recessed to leave a plurality of second openings with substantially equal depths in each of the trenches.

### BACKGROUND OF THE INVENTION

1. Field of the Invention

The present invention relates to a method of improving photoresist layer uniformity, and in particular to fabricating a lower electrode of a trench capacitor by executing the method.

2. Description of the Related Art

DRAM is capable of reading and writing information. Each DRAM cell needs only one transistor and one capacitor; therefore, it is easy to reach higher integration to make it broadly applicable to computers and electronic equipment. A trench capacitor, formed in the semiconductor silicon substrate, is one of the most commonly used capacitors. With the enhancement of the depth of the trench capacitor in the semiconductor silicon substrate, the surface area of the trench capacitor is increased, so that capacitance is increased. The chip with trench capacitors can be separated into a memory cell array area used to store data and a decoupling capacitor area used to filter noise.

In the conventional fabricating method of trench capacitors, many trenches are formed in a semiconductor silicon substrate. An As-doped silicon oxide layer is covered with the semiconductor silicon substrate with trenches. The silicon oxide layer is patterned with lower electrode patterns by coating and baking a photoresist. The photoresist can flow into the trenches in the baking step. Then the hardened photoresist, after baking, is removed by dry etching until the upper surface of the photoresist is lower than that of the semiconductor silicon substrate by a predetermined distance. The exposed silicon oxide layer is removed using the photoresist as a mask. Then, the doped As ions in the silicon oxide layer are driven into the semiconductor silicon substrate to form a conducting layer as a lower electrode of the trench capacitor. The capacitance of the trench capacitor is related to the surface area of the lower electrode, determined by the area of the silicon oxide layer covering the trench. The area of the silicon oxide layer covering the trench is controlled by the distance between the upper surface of the photoresist and that of the semiconductor silicon substrate. However, the distance is difficult to control.

Adhesion between the photoresist and the silicon oxide layer is too weak to drive the photoresist flow into the trench after spin coating. During the baking of the photoresist, the photoresist can flow into the trenches. Nevertheless, the densities of the trenches in the memory cell array area and in the decoupling capacitor area are different. A mass of the photoresist flows into the trenches in the higher density area (the memory cell array area) so that the surface of the hardened photoresist is lower. A small quantity of the photoresist flows into the trenches in the lower density area (the decoupling capacitor area) so that the surface of the hardened resist is higher. Therefore, there is a height difference between the surfaces of the hardened resist in different areas.

In FIG. 1A, the photoresist layer 104 has poor uniformity, caused by the reasons mentioned. After photoresist recessing, the distances between the upper surface of the recessed photoresist layer 104a and surface of the substrate 100 in each of the trenches are difficult to control, as shown in FIG. 1B.

Moreover, the difference between the distances between the upper surface of the photoresist and that of the semiconductor silicon substrate in different trenches exists after etching the photoresist. For example, under the design rule of 0.175 μm, the above-mentioned difference reaches 8200 Å. In order to prevent the lower electrode in the lower density area (the decoupling capacitor area) and the buried strap (or called ion doped band) from subsequently forming in the top of the semiconductor silicon substrate by shorting, the lower electrode formed in the memory cell array area has a smaller surface area, which will damage the storage performance. In order to-enhance the surface area of the lower electrode in the memory cell array area, the breakdown voltage between the lower electrode in the decoupling capacitor area and the buried strap will be reduced, and may even short the circuit. Therefore, there is difficulty in etching the photoresist. It is possible that the whole process may fail.

In order to solve the problem of uniformity of the photoresist layer, a method of improving uniformity of the photoresist layer is used, to modify the substrate to enhance the adhesion between the substrate and the photoresist layer. The modification of the substrate comprises an oxygen plasma treatment, a wet treatment with a mixed solution of H₂SO₄ and H₂O₂, or a wet treatment with a mixed solution of NH₄OH and H₂O₂. After this modification, the difference between the upper surfaces of the recessed photoresist layer in each of the trenches is controlled and reduced by 3000˜4000 Å.

However, when the design rule reaches 0.11 μm, the difference between non-uniformity of the recessed photoresist layer in each of the trenches can reach 7000˜8000 Å. It is still necessary to improve uniformity of the photoresist layer.

### SUMMARY OF THE INVENTION

Accordingly, an object of the present invention is to provide a method of improving photoresist layer uniformity to effectively control the distance between the surface of the substrate and the upper surface of the photoresist layer under different densities in trenches.

It is another object of the present invention to provide a method of fabricating a lower electrode of a trench capacitor, to prevent the capacitors in the decoupling capacitor area from invalidation, and prevent the capacitance reduction in the memory cell array area.

It is still another object of the present invention to provide a method of fabricating a lower electrode of a trench capacitor to increase breakdown voltage between the lower electrode and the dopants and enhance the reliability of the trench capacitor.

It is a further object of the present invention to provide a method of fabricating a lower electrode of a trench capacitor to enhance the yield of the manufacturing of the lower electrode of the trench capacitor.

The key feature of the present invention is conformal deposition of the refill photoresist layer after the conventional photoresist layer recessing, such that the space between the recessed photoresist layer (the protective photoresist layer) and the surface of the substrate, caused by poor adhesion between the photoresist layer and the substrate and uniformity of the densities of the trenches, is refilled by the refill photoresist layer with a planar upper surface. After photoresist layer recessing, the upper surface of the photoresist layer, consisting of the protective photoresist layer and the refill photoresist layer, maintains a substantially equal distance in each of the trenches with the surface of the substrate because the refill photoresist layer is uniform.

To achieve these and other advantages, the invention provides a method of improving photoresist layer uniformity. First, a substrate having a plurality of trenches is provided. Next, a protective photoresist layer is formed on the substrate to fill the trenches. Parts of the protective photoresist layer are removed to form first openings in trenches. A refill photoresist layer with a planar upper surface is blanketly formed to fill the first openings. The protective photoresist and/or the refill photoresist layer are recessed to leave a plurality of second openings with substantially equal depths in each of the trenches.

A nitride is further formed on the substrate except the trenches. The nitride serves as a stop layer for removing parts of the protective photoresist layer to form first openings in the trenches.

The protective photoresist layer and the refill photoresist layer comprise the same material.

The invention also provides a method of fabricating a lower electrode of a trench capacitor. First, a substrate is provided. Next, a hard mask having a plurality of openings is formed on the substrate. The substrate is etched through the openings of the hard mask to form a plurality of trenches. A dielectric layer comprising dopants is formed conformally on the surface and the side walls of the trenches. A protective photoresist layer is formed on the hard mask and the dielectric layer to fill the trenches. Parts of the protective photoresist layer are then removed until the hard mask is exposed, such that parts of the upper surface of the protective photoresist layer are lower than the surface of the hard mask to form first openings in the trenches. A refill photoresist layer with a planar upper surface is formed blanketly to fill the first openings. The protective photoresist and/or the refill photoresist layer are recessed to leave a plurality of second openings with substantially equal depths in each of the trenches and expose parts of the dielectric layer. After removing the exposed parts of the dielectric layer, the remaining protective photoresist and refill photoresist layer are removed. Finally, the dopants are driven into the substrate to form a lower electrode.

The protective photoresist layer and the refill photoresist layer comprise the same material.

The hard mask comprises a nitride. As well, a pad oxide is further formed between the substrate and the hard mask.

According to the present invention, the trenches can comprise a plurality of dense trenches and an isolated trench. After recessing the protective photoresist and/or the refill photoresist layer, the second openings have substantially equal depths in the dense trenches and the isolated trench.

### BRIEF DESCRIPTION OF THE DRAWINGS

The present invention can be more fully understood by reading the subsequent detailed description and examples with references made to the accompanying drawings, wherein:

FIGS. 1A through 1B are cross-sections showing non-uniformity of the photoresist layer according to the conventional process;

FIGS. 2A through 2I are cross-sections showing the method of fabricating a lower electrode of a trench capacitor by executing the method of improving planarity of the photoresist according to a preferred embodiment of the present invention;

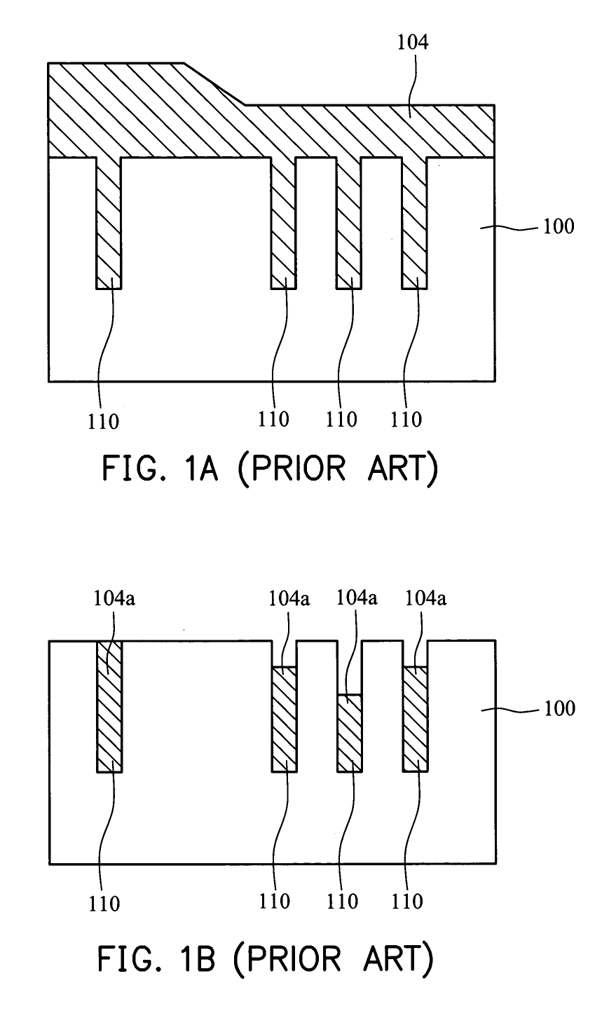

### DETAILED DESCRIPTION OF THE INVENTION

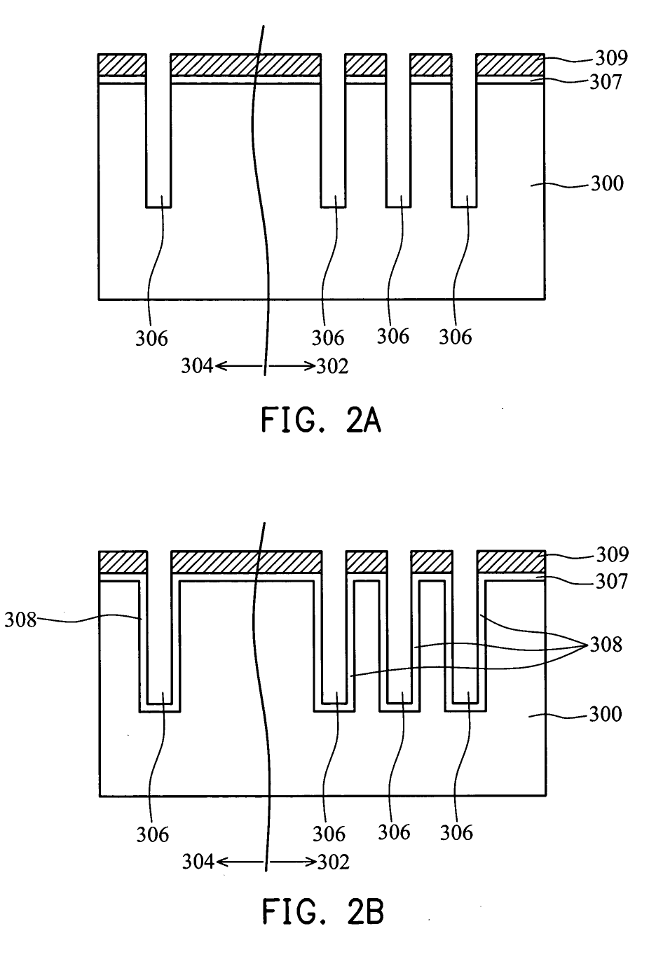

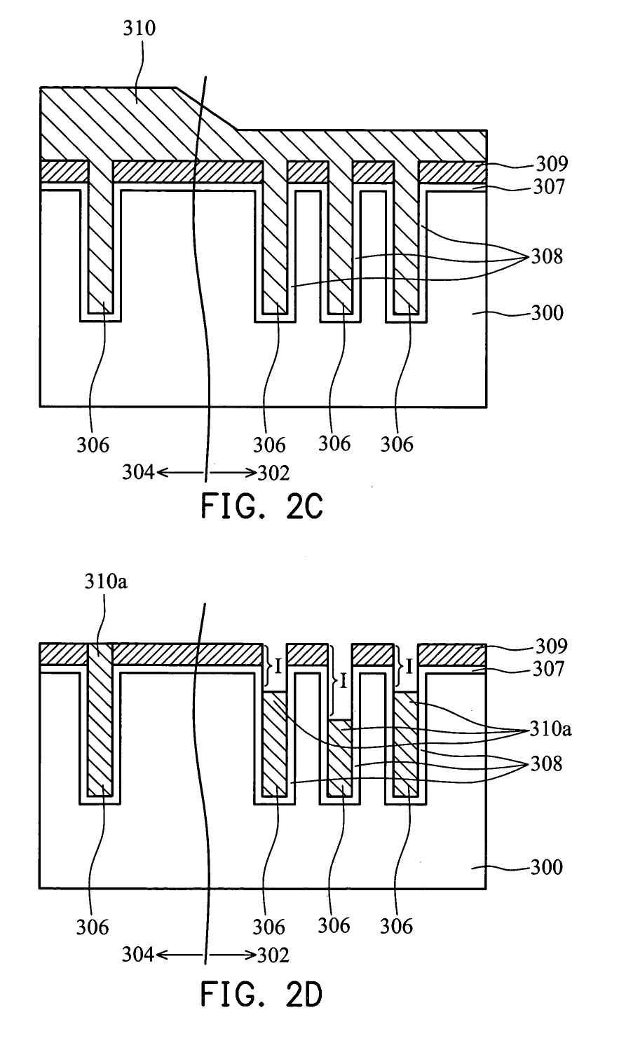

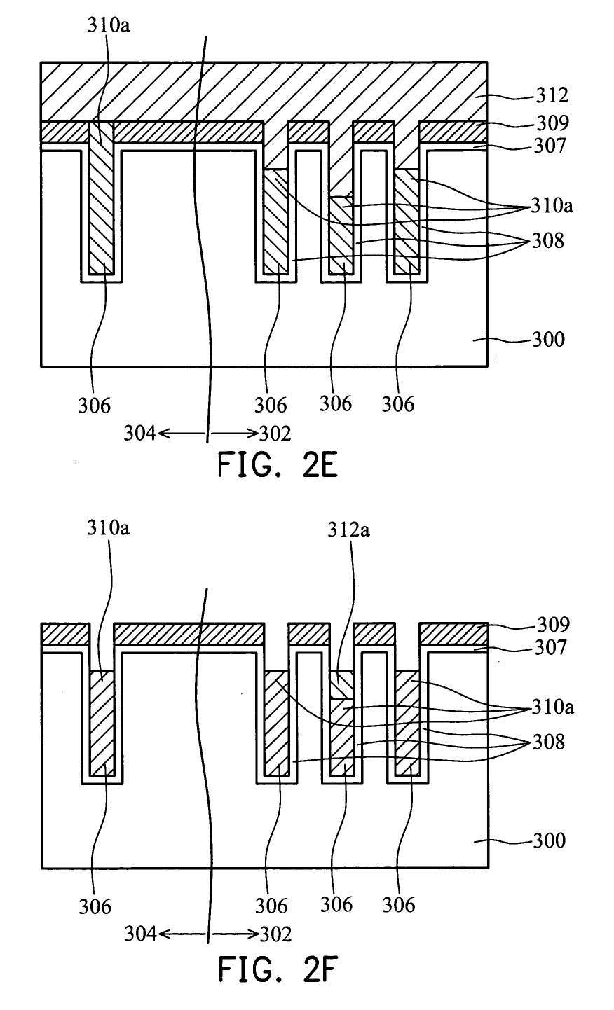

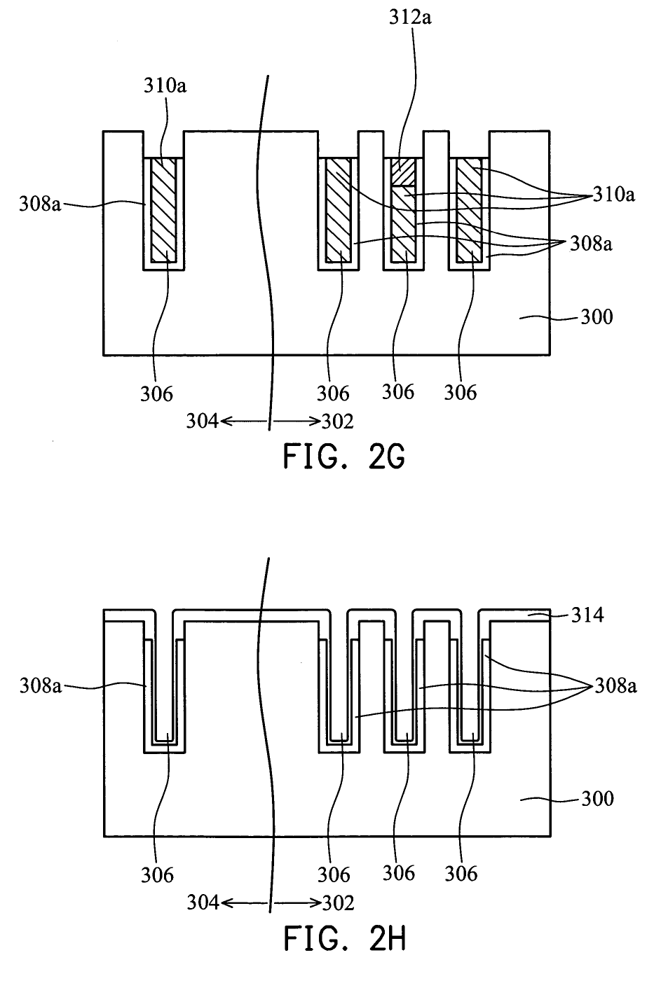

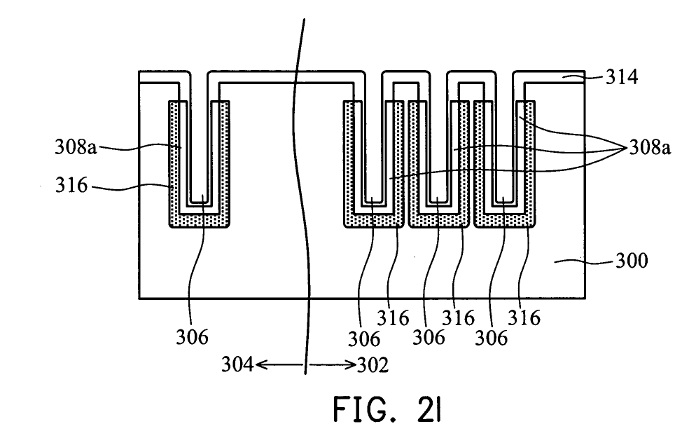

A preferred embodiment of the present invention is now described with reference to FIGS. 2A to 2I.

First, a substrate 300, comprising a memory cell array area 302 and a decoupling capacitor area 304, is provided, as shown in FIG. 2A. A hard mask 309 having a plurality of openings is formed on the substrate 300. The material of the substrate 300 comprises silicon. As well, the material of the hard mask 309 comprises a nitride. A pad oxide 307 is preferably formed between the substrate 300 and the hard mask 309 to enhance adhesion of the hard mask 309. The substrate 300 is etched through the openings of the hard mask 309 to form a plurality of trenches 306. In the memory cell array area 302, there is a plurality of dense trenches. In the decoupling capacitor area 304, there are isolated trenches.

Next, a dielectric layer 308 comprising dopants is conformally formed on the surface and the side walls of the trenches 306, as shown in FIG. 2B. The dopants comprise phosphorous (P) or arsenic (As). The dielectric layer 308 comprising silicon oxide (SiO₂) is preferably formed by chemical vapor deposition.

In FIG. 2C, a protective photoresist layer 310 is preferably formed on the hard mask 309 and the dielectric layer 308 by spin coating to fill the trenches 306. The uniformity of the protective photoresist layer 310 is poor, caused by poor adhesion between the protective photoresist layer 310 and the hard mask 309 and the density differences between the trenches in the dense trenches and the isolated trench.

In FIG. 2D, parts of the protective photoresist layer 310 are preferably removed by etching until the hard mask 309 is exposed. Parts of the upper surface of the protective photoresist layer 310 are lower than the surface of the hard mask 309 to form first openings I in the trenches. After forming the first openings I, the upper surfaces of the protective photoresist layer 310 in each of the trenches 306 maintain different distances from the surface of the substrate 300, resulting from poor uniformity of the protective photoresist layer 310.

In FIG. 2E, a refill photoresist layer 312 with a planar upper surface is blanketly formed to fill the first openings I. The key feature of the present invention is deposition of the refill photoresist layer 312 for refilling the first openings I and formation of a planar upper surface on the entire substrate 300. The refill photoresist layer 312 and the protective photoresist layer 310 can be made of the same materials.

In FIG. 2F, the protective photoresist 310 and/or the refill photoresist layer 312 are recessed by etching to leave a plurality of second openings with substantially equal depths in each of the trenches, thereby parts of the dielectric layer 308 are exposed. The removed photoresist layer can consist of only the protective photoresist 310 or a combination of the protective photoresist 310 and the refill photoresist layer 312.

In FIG. 2G, the exposed parts of the dielectric layer 308 are preferably removed by wet etching using the remaining protective photoresist layer 310 and refill photoresist layer 312 as a mask.

In FIG. 2H, the remaining protective photoresist and refill photoresist layer are removed by SPM comprising H₂SO₄ and H₂O₂.

In FIG. 2H, a conformal oxide 314 is preferably formed on the surface and the side walls of the trenches 306. Finally, the dopants contained in the dielectric layer 308a are driven into the substrate 300 around the trenches 306 by thermal process to form a lower electrode 316. The conformal oxide 314 can prevent the dopants diffusing into the reactive chamber during thermal process.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A method of improving photoresist layer uniformity, comprising:
providing a substrate having a plurality of trenches;
forming a protective photoresist layer on the substrate to fill the trenches;
removing parts of the protective photoresist layer to form first openings in the trenches;
blanketly forming a refill photoresist layer with a planar upper surface to fill the first openings;
recessing the protective photoresist and/or the refill photoresist layer to leave a plurality of second openings with substantially equal depths in each of the trenches.

2. The method as claimed in claim 1, wherein a nitride is further formed on the substrate excepting the trenches.

3. The method as claimed in claim 2, wherein the nitride serves as a stop layer for removing parts of the protective photoresist layer to form first openings in the trenches.

4. The method as claimed in claim 1 wherein the protective photoresist layer and the refill photoresist layer comprise the same material.

5. A method of fabricating a lower electrode of a trench capacitor, comprising:
providing a substrate;
forming a hard mask having a plurality of openings on the substrate;
etching the substrate through the openings of the hard mask to form a plurality of trenches;
conformally forming a dielectric layer comprising dopants on the surface and the side walls of the trenches;
forming a protective photoresist layer on the hard mask and the dielectric layer to fill the trenches;
removing parts of the protective photoresist layer until the hard mask is exposed, such that parts of the upper surface of the protective photoresist layer are lower than the surface of the hard mask to form first openings in the trenches;
blanketly forming a refill photoresist layer with a planar upper surface to fill the first openings;
recessing the protective photoresist and/or the refill photoresist layer to leave a plurality of second openings with substantially equal depths in each of the trenches and expose parts of the dielectric layer;
removing the exposed parts of the dielectric layer;
removing the protective photoresist and the refill photoresist layer; and
driving the dopants into the substrate to form a lower electrode.

6. The method as claimed in claim 5, wherein the protective photoresist layer and the refill photoresist layer comprise the same material.

7. The method as claimed in claim 5, wherein the hard mask comprises a nitride.

8. The method as claimed in claim 5, wherein a pad oxide is further formed between the substrate and the hard mask.

9. A method of fabricating a lower electrode of a trench capacitor, comprising:
providing a substrate;
forming a hard mask having a plurality of openings on the substrate;
etching the substrate through the openings of the hard mask to form a plurality of trenches, wherein the trenches comprise a plurality of dense trenches and an isolated trench;
conformally forming a dielectric layer comprising dopants on the surface and the side walls of the trenches;
forming a protective photoresist layer on the hard mask and the dielectric layer to fill the trenches;
removing parts of the protective photoresist layer until the hard mask is exposed, such that parts of the upper surface of the protective photoresist layer are lower than the surface of the hard mask to form first openings in the trenches;
blanketly forming a refill photoresist layer with a planar upper surface to fill the first openings;
recessing the protective photoresist and/or the refill photoresist layer to leave a plurality of second openings with substantially equal depths in the dense trenches and the isolated trench and expose parts of the dielectric layer;
removing the exposed parts of the dielectric layer;
removing the protective photoresist and the refill photoresist layer; and
driving the dopants into the substrate to form a lower electrode.

10. The method as claimed in claim 9, wherein the protective photoresist layer and the refill photoresist layer comprise the same material.

11. The method as claimed in claim 9, wherein the hard mask comprises a nitride.

12. The method as claimed in claim 9, wherein a pad oxide is further formed between the substrate and the hard mask.
